(19) United States
(12) Patent Application Publication
(10) Pub. No.: US 2026/0178277 A1
(43) Pub. Date: Jun. 25, 2026

(54) Digital Signal Processing (DSP) Block with Systolic Filter Support Circuitry

(71) Applicant: Altera Corporation, San Jose, CA (US)

(72) Inventors: Martin Langhammer, Alderbury (GB); Dongdong Chen, San Jose, CA (US); Jason Bergendahl, Cupertino, CA (US); Volker Mauer, Princes Risborough (GB)

(21) Appl. No.: 18/988,363

(22) Filed: Dec. 19, 2024

(51) Int. Cl. G06F 7/544; H03K 19/173; H03K 19/17704

(52) U.S. Cl. CPC G06F 7/5443; H03K 19/1737; H03K 19/17712

(57) ABSTRACT

Integrated circuit devices and circuitry for digital filtering are provided. An integrated circuit device may include a first digital signal processing (DSP) block with first hardened arithmetic circuitry and an output register to store an output of the first DSP block and a second DSP block with second hardened arithmetic circuitry and an input register to receive the output of the first DSP block. An input signal chain may include a first set of registers to provide first input data signals to the first DSP block, a second set of registers to provide second input data signals to the second DSP block, and a third set of registers connected between the first set of registers and the second set of registers to provide delay equal to that of the output register of the first DSP block and the input register of the second DSP block.

### BACKGROUND

This disclosure relates to systolic filtering using digital signal processing (DSP) blocks of an integrated circuit, such embedded DSP blocks of a field programmable gate array (FPGA).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Many integrated circuits include arithmetic circuit blocks to perform arithmetic operations such as addition and multiplication. For example, a digital signal processing (DSP) block may supplement programmable logic circuitry in a programmable logic device, such as a field programmable gate array (FPGA). Programmable logic circuitry and DSP blocks may be used to perform numerous different arithmetic functions. Finite impulse response (FIR) filters are one of the most used application areas for FPGA. Many DSP blocks used in FPGAs have supported 1-tap or 2-tap systolic filtering. Even with this support, implementing a large filter may consume a large number of DSP blocks.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of the integrated circuit device of FIG. 1;

FIG. 3 is a block diagram of a finite impulse response (FIR) filter that may be formed using multipliers formed using digital signal processing (DSP) blocks of the integrated circuit device;

FIG. 4 is a diagram showing retiming of a portion of a FIR filter using a DSP block of the integrated circuit device;

FIG. 5 is a diagram showing multiple retimed portions of a FIR filter chained together across multiple DSP blocks;

FIG. 6 is a diagram of a four-tap systolic FIR filter;

FIG. 7 is a diagram of a first retimed four-tap systolic FIR filter with a first additional set of registers;

FIG. 8 is a diagram of a second retimed four-tap systolic FIR filter with a second additional set of registers;

FIG. 9 is a diagram of chained 4-tap systolic FIR filters across multiple 4-multiplier DSP blocks;

FIG. 10 is a block diagram of tensor circuits of a DSP block that can be used to form systolic FIR filters;

FIG. 11 is a block diagram illustrating the implementation of a systolic FIR filter using tensor circuits of a DSP block;

FIG. 12 is a block diagram of multiple DSP blocks chained together to implement a tensor systolic FIR filter using tensor circuits of the DSP blocks;

FIG. 13 is a block diagram of multiple DSP blocks chained together to implement a higher-precision tensor systolic FIR filter using tensor circuits of the DSP blocks;

FIG. 14 is a block diagram of a tensor circuit with multiple register banks to enable multi-channel filters;

FIG. 15 is a block diagram of a tensor circuitry with multiple register banks and multiple multiplexers per multiplier to enable multi-channel filtering; and

FIG. 16 is a block diagram of a data processing system that may incorporate the integrated circuit.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

Many integrated circuits, such as programmable logic devices, include DSP blocks. DSP blocks include “hardened” circuits that are specialized to efficiently perform certain mathematical operations. This is in contrast to “soft” circuits that may be formed by programming programmable logic, but which may not be as efficient. One desirable use case for DSP blocks is digital filtering. To this end, some DSP blocks may include cascade registers to receive cascaded data directly from one DSP block to another DSP block, an output register to hold data to pass from one DSP block to another DSP block, circuitry to support a systolic mode that enables 2-tap finite impulse response (FIR) filters in a single DSP block, which may be connected to other DSP blocks to form larger FIR filters. Increasingly, DSP blocks in integrated circuit devices may include more large multipliers than DSP blocks of previous generations. To enable efficient systolic filters in DSP blocks with more multipliers while retaining backward compatibility with DSP blocks of previous generations of integrated circuit devices with fewer multipliers, register retiming may be used to create equivalent circuits that efficiently chain together any suitable number of DSP blocks. Since many adjacent DSP blocks may be formed into a column on an integrated circuit device, this may allow a column of DSP blocks to form a multi-tap filter substantially contained within a DSP block column.

Some DSP blocks may include artificial intelligence (AI) circuitry that includes a large number of smaller multipliers with lower precisions than typically found in many DSP use cases. These may form large tensors, which compute dot products, that are implemented in the hardware of the DSP blocks. Rather than allow the AI-related circuitry of the DSP blocks simply to go unused when a programmable logic device is being used in filtering operations, the AI-related circuitry may provide additional regular DSP functions. For example, AI tensor cores of DSP blocks may be used in FIR filters. This may double (or more) the arithmetic density of FIR filters, largely by repurposing a hardened resource typically used for AI operations for digital signal processing operations instead.

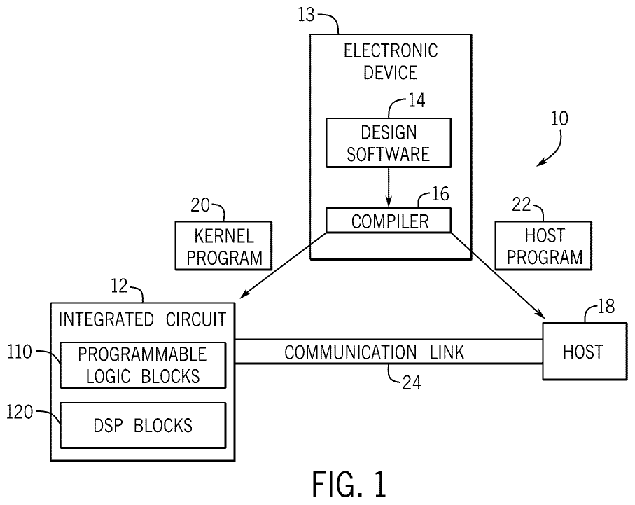

FIG. 1 illustrates a block diagram of a system 10 that may be used to implement the filtering systems and methods of this disclosure on an integrated circuit system 12 (e.g., a single monolithic integrated circuit or a multi-die system of integrated circuits). A designer may desire to implement a system design to perform filtering operations on the integrated circuit system 12 (e.g., a programmable logic device such as a field-programmable gate array (FPGA) or an application-specific integrated circuit (ASIC) that includes programmable logic circuitry). The integrated circuit system 12 may include a single integrated circuit, multiple integrated circuits in a package, or multiple integrated circuits in multiple packages communicating remotely (e.g., via wires or traces) and may be referred to as an integrated circuit device whether formed from a single integrated circuit or multiple integrated circuits in a package. In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

In a configuration mode of the integrated circuit system 12, a designer may use an electronic device 13 (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit system 12. The host 18 may receive a host program 22 that may control or be implemented by the kernel programs 20. To implement the host program 22, the host 18 may communicate instructions from the host program 22 to the integrated circuit system 12 via a communications link 24 that may include, for example, direct memory access (DMA) communications or peripheral component interconnect express (PCIe) communications. In some embodiments, the kernel programs 20 and the host 18 may configure programmable logic blocks (e.g., LABs 110) on the integrated circuit system 12. The programmable logic blocks (e.g., LABs 110) may include circuitry and/or other logic elements and may be configurable to implement a variety of functions in combination with digital signal processing (DSP) blocks 120.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

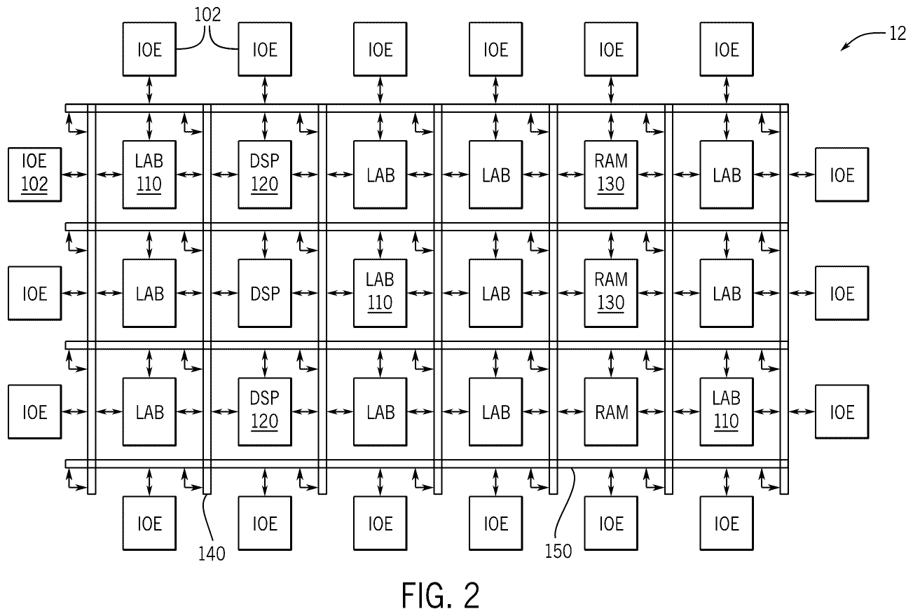

An illustrative embodiment of a programmable integrated circuit system 12 such as a programmable logic device (PLD) (e.g., a field programmable gate array (FPGA) device) that may be configured to implement a circuit design (also sometimes referred to as a system design) is shown in FIG. 2. The integrated circuit system 12 (e.g., a field-programmable gate array (FPGA) integrated circuit device) may include a two-dimensional array of functional blocks sometimes referred to as programmable logic blocks (e.g., also referred to as logic array blocks (LABs) 110 or configurable logic blocks (CLBs)) that may include some number of adaptive logic modules (ALMs) that may be programmed to behave as particular logic circuitry. The integrated circuit system 12 may also include other functional blocks, such as embedded digital signal processing (DSP) blocks 120 and embedded random-access memory (RAM) blocks 130. Functional blocks such as LABs 110 may include smaller programmable regions (e.g., logic elements, configurable logic blocks, or adaptive logic modules) that receive input signals and perform custom functions on the input signals to produce output signals. LABs 110 may also be grouped into larger programmable regions, sometimes referred to as logic sectors, that are individually managed and configured by corresponding logic sector managers. The grouping of the programmable logic resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy.

Programmable logic circuitry of the integrated circuit system 12 may be controlled by programmable memory elements sometimes referred to as configuration random access memory (CRAM). Memory elements may be loaded with configuration data (also called programming data or a configuration bitstream) using input-output elements (IOEs) 102. Once loaded, the memory elements each provide a corresponding static control signal that controls the operation of an associated functional block (e.g., LABs 110, DSP BLOCK 120, RAM 130, or input-output elements 102).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory (ROM) memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements. The integrated circuit system 12 (e.g., as a programmable logic device (PLD)) may be configured to implement a custom circuit design. For example, the configuration RAM may be programmed such that LABs 110, DSP BLOCK 120, and RAM 130, programmable interconnect circuitry (e.g., vertical channels 140 and horizontal channels 150), and the input-output elements 102 form the circuit design implementation.

In addition, the programmable logic device may have input-output elements (IOEs) 102 for driving signals off the integrated circuit system 12 and for receiving signals from other devices. Input-output elements 102 may include parallel input-output circuitry, serial data transceiver circuitry, differential receiver and transmitter circuitry, or other circuitry used to connect one integrated circuit to another integrated circuit.

The integrated circuit system 12 may also include programmable interconnect circuitry in the form of vertical routing channels 140 (i.e., interconnects formed along a vertical axis of the integrated circuit system 12) and horizontal routing channels 150 (i.e., interconnects formed along a horizontal axis of the integrated circuit system 12), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 2, are intended to be included within the scope of the present disclosure. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit system 12, fractional global wires such as wires that span part of the integrated circuit system 12, staggered wires of a particular length, smaller local wires, or any other suitable interconnection resource arrangement.

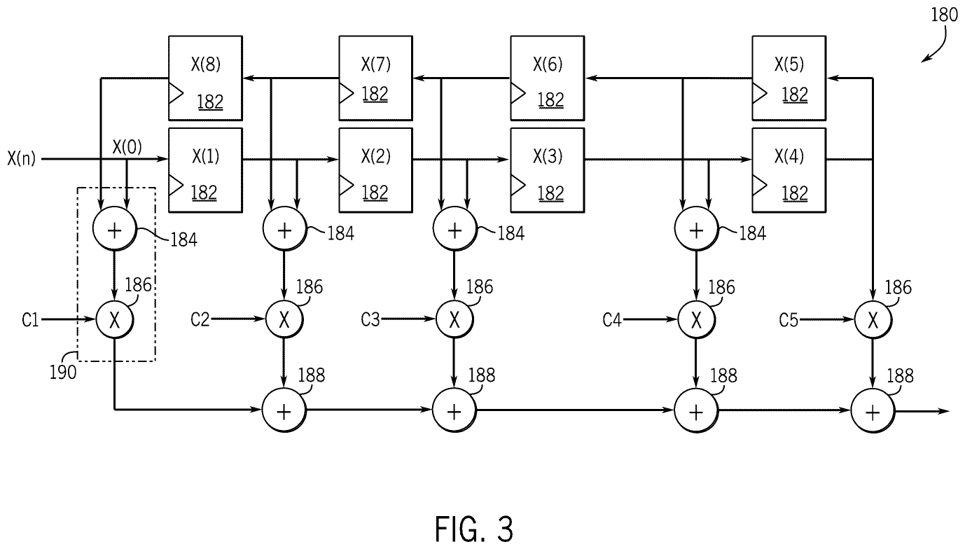

The integrated circuit 12 may be programmed to perform a wide variety of operations. One example shown in FIG. 3 is finite impulse response (FIR) filtering. For example, a FIR filter may be an asymmetric FIR filter in which weights applied to different taps may be different or, in the example of FIG. 3, may be a symmetric FIR filter 180 in which the weights are the same magnitude around some defined point. In the example of FIG. 3, the symmetric FIR filter 180 receives an input signal x(n). The FIR filter 180 illustrated in FIG. 3 has 9 taps symmetric to a point x(4) of the signal x(n) when the first point in the x(n) signals is x(0). The x(n) signal traverses registers 182 that provide the tap points into a pre-adder 184 before the results enter a multiplier 186 to multiply by a weight value (here, coefficients C1, C2, C3, C4, or C5). The partial results are summed together in adders 188 to obtain the result of the filter 180. The adders 184 and the multipliers 186 may be effectively grouped into a single operation 190 in some instances. In some cases, the weights may have the same magnitude, but a different sign. In such cases, the pre-adder 184 may be configurable as a presubtractor. The adders 188 may be separate addition circuits or a single large summation circuit.

A wide variety of filters, such as the FIR filter 180 of FIG. 3, may be formed using circuitry of the integrated circuit system 12. The multiplication of the filters may take place using AI-related circuits on the DSP blocks 120 and/or large multipliers (e.g., 18×18 multipliers, 27×27 multipliers) of the DSP blocks 120. By retiming registers of the DSP blocks 120 and/or programmable logic circuitry (e.g., LABs 110), multi-tap FIR filters may be formed that span multiple DSP blocks 120.

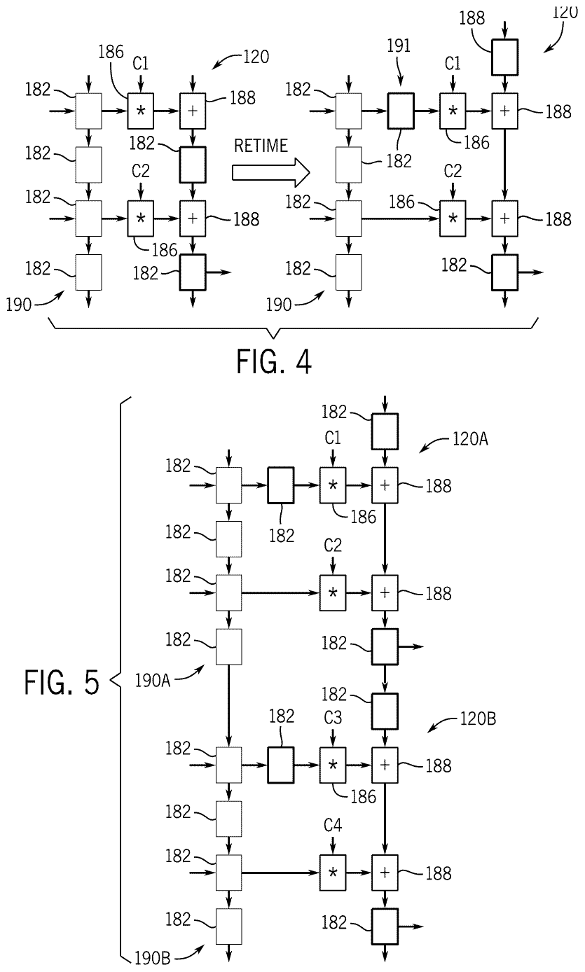

FIG. 4 illustrates the effect of retiming a two-tap FIR filter formed using a DSP block 120. The structure on the lefthand side of FIG. 4 represents an original un-retimed circuit that includes a data signal chain 190 of registers 182 that pass data signals (e.g., x(n)) to multipliers 186 that multiply the data signals by a coefficient (e.g., C1, C2). The results are added in adders 188, which are separated by one register 182. The placement of the registers 182 may be adjusted through retiming. Retiming is a process whereby the registers 182 may be shifted or added, but the resulting circuit is functionally equivalent. Retiming is normally performed to shorten a critical path of a circuit design to enable a higher maximum operating frequency. Here, retiming the two-tap filter on the lefthand side of FIG. 4 may result in the same operating frequency and an advantageous adder structure. The retimed circuit is shown on the righthand side of FIG. 4. The register 182 between the adders 188 may be removed while new registers 182 are added. The added registers 182 include a delay register 191 that connects to the data signal chain 190 of registers 182 before the upper adder 188 and another register 182 before the upper multiplier 186. Note that this adds one cycle of latency but produces the same result as structure on the lefthand side. Moreover, since there is no longer delay between the adders 188, the adders 188 may be combined into a single addition structure. This is valuable because, in hardware, it is much more efficient to add a group of numbers together in a single structure compared to using multiple discrete structures. In other words, the retimed structure shown on the righthand side of FIG. 4 may operate more efficiently because the adders 188 may be a single addition structure.

Moreover, multiple such retimed FIR filter circuits may be combined across multiple DSP blocks 120, as shown in FIG. 5. Here, a four-tap filter is formed using two DSP blocks 120A and 120B that have been retimed in the manner discussed above with reference to FIG. 4. The four-tap filter of FIG. 5 multiplies a data signal supplied by connected data signal chains 192A and 194B of registers 182 by four coefficients C1, C2, C3, and C4. Although FIG. 4 illustrates the use of two DSP blocks 120A and 120B that respectively perform two multiplications per DSP block 120, a single DSP block 120 with more multipliers 186 (e.g., four multipliers) may also be arranged in the same way.

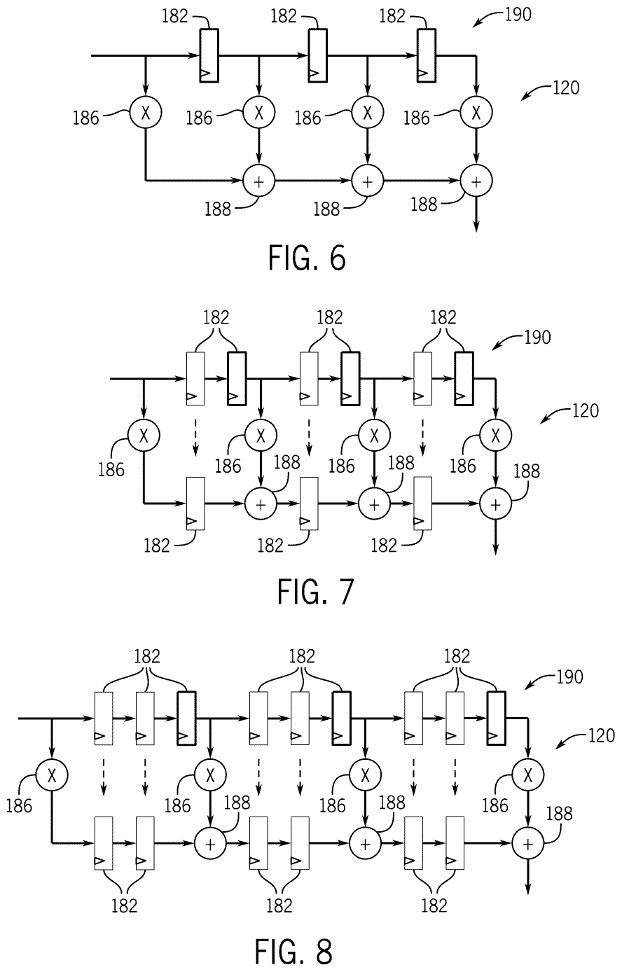

Indeed, any suitable FIR filter may be retimed by adding registers between stages without changing the result of the filter except to add latency. But adding a few clock cycles of latency may be worthwhile to gain greater computational efficiency (e.g., more efficient addition) and/or to enable multiple DSP blocks 120 to be chained together to produce a larger multi-tap filter. FIGS. 6-8 provide examples of retiming a FIR filter to produce equivalent structures with slightly higher latency. FIG. 6 illustrates a DSP block 120 with four multipliers 186 that receive data from a data signal chain 190 of registers 182. The multipliers 186 may multiply data from the data signal chain 190 of registers 182 by any suitable coefficients (not shown) and the products may be summed in adders 188 to produce a filter result. FIG. 7 is an equivalent FIR filter to that shown in FIG. 6 except with additional latency. In FIG. 7, an additional register 182 is added to the data signal chain 190 of registers 182 carrying input data before each multiplier 186 and a corresponding register 182 is added following each multiplier 186. As a consequence, the data is delayed before multiplication and the product of the multiplication is also delayed before addition, producing an equivalent filter result but with more delay than in FIG. 6. This may be extended using any suitable number of registers 182. As shown in FIG. 8, a second additional register 182 is added to the data signal chain 190 of registers 182 carrying input data before each multiplier 186 and a second corresponding register 182 is added following each multiplier 186. The resulting FIR filter of FIG. 8 is functionally the same as that of FIG. 6 and FIG. 7 except for additional latency.

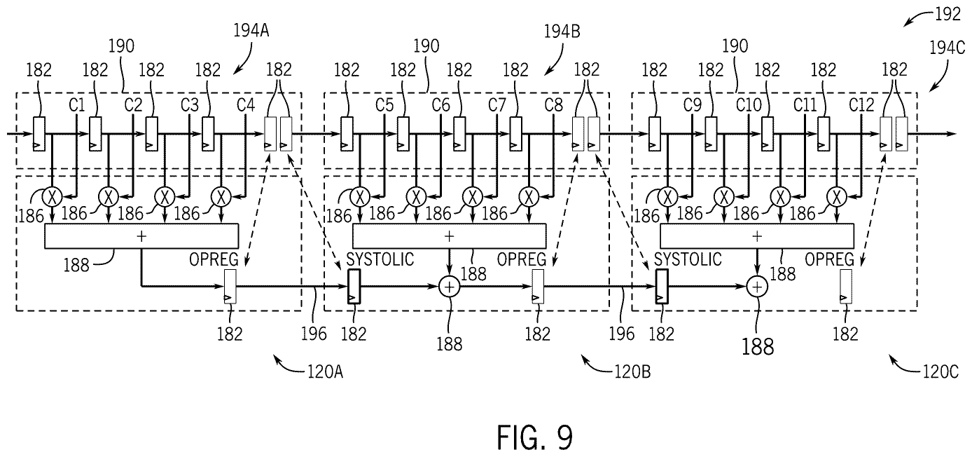

This principle of adding registers may be used to implement multi-tap filters across multiple DSP blocks 120. For example, FIG. 9 illustrates a 12-tap FIR filter 192 formed from three 4-tap FIR filters 194A, 194B, and 194C that are connected in series. Each FIR filter 194A, 194B, and 194C receives input data signals from a chain 190 of registers 182 (e.g., implemented in programmable logic circuitry, such as programmable routing circuitry 140 or 150 and/or LABs 110, and/or implemented in hardened circuitry) that feed into multipliers 186 of a DSP block 120A, 120B, or 120C. Here, each DSP block 120A, 120B, and 120C includes four multipliers 186. The DSP block 120A includes an adder 188 that sums the product of its four multipliers 186, which multiply input data by coefficients C1, C2, C3, and C4. The summed result from the adder 188 of the DSP block 120A is held in an output register (opreg) register 182. The value held by the output register (opreg) register 182 is provided via a direct path 196 to a systolic input register (systolic) register 182 of the DSP block 120B. A direct path 196 may connect each adjacent DSP block 120 in a column of DSP blocks 120 of the integrated circuit system to enable the filter results to traverse directly from one DSP block 120 to another DSP block 120 without using additional programmable routing or programmable logic block resources.

To enable the DSP block 120A to chain into the DSP block 120B, effectively joining two four-tap FIR filters 194A and 194B without changing the operation of the overall FIR filter except to add latency, two additional delay registers 182 are included at the end of the chain 190 of registers 182 of the first FIR filter 194A. These two delay registers 182 of the chain 190 of registers 182 of the FIR filter 194A provide an equivalent amount of delay respectively corresponding to the output register (“opreg”) register 182 of the DSP block 120A and the systolic input register (“systolic”) register 182 of the DSP block 120B. This adds two cycles of latency but enables the formation of a multi-tap filter across multiple DSP blocks 120 that uses more multipliers than may be found in a single DSP block 120.

Indeed, the second four-tap FIR filter 194B based on the DSP block 120B is further connected to the third four-tap FIR filter 194C based on the DSP block 120C. The DSP block 120B includes two adders 188: one adder 188 that sums the product of its four multipliers 186, which multiply input data by coefficients C5, C6, C7, and C8, and one adder 188 to add the result of the first adder 188 to the value held by the systolic input register (“systolic”) register 182 of the DSP block 120B. Note that these two adders 188 of the DSP block 120B may be combined into a single larger adder structure. In any event, because the two adders 188 are connected without an intervening register 182, even if the two adders 188 are separate structures, they will still produce a sum in a single clock cycle. The summed result from the second adder 188 of the DSP block 120B is held in an output register (“opreg”) register 182. The value held by the output register (“opreg”) register 182 of the DSP block 120B is provided to a systolic input register (“systolic”) register 182 of the DSP block 120C via the direct path 196 between them.

To enable the DSP block 120B to chain into the DSP block 120C, two additional delay registers 182 are included at the end of the chain 190 of the FIR filter 194B. These two final registers 182 of the chain 190 of the FIR filter 194B correspond respectively to the output register (“opreg”) register 182 of the DSP block 120B and the systolic input register (“systolic”) register 182 of the DSP block 120C. This adds two cycles of latency, but enables the DSP block 120B and 120C to be connected together in a larger multi-tap FIR filter. The DSP block 120C includes multipliers 186 that multiply input data by coefficients C9, C10, C11, and C12. The DSP block 120C may also include two adders 188: one adder 188 that sums the product of its four multipliers 186 and one adder 188 to add the result of the first adder 188 to the value held by the systolic input register (“systolic”) register 182 of the DSP block 120C. Note that these two adders 188 of the DSP block 120C may be combined into a single larger adder structure. The summed result from the second adder 188 of the DSP block 120C may be output as the result of the overall FIR filter 191 and an output register (“opreg”) register 182 of the DSP block 120C may be unused or repurposed.

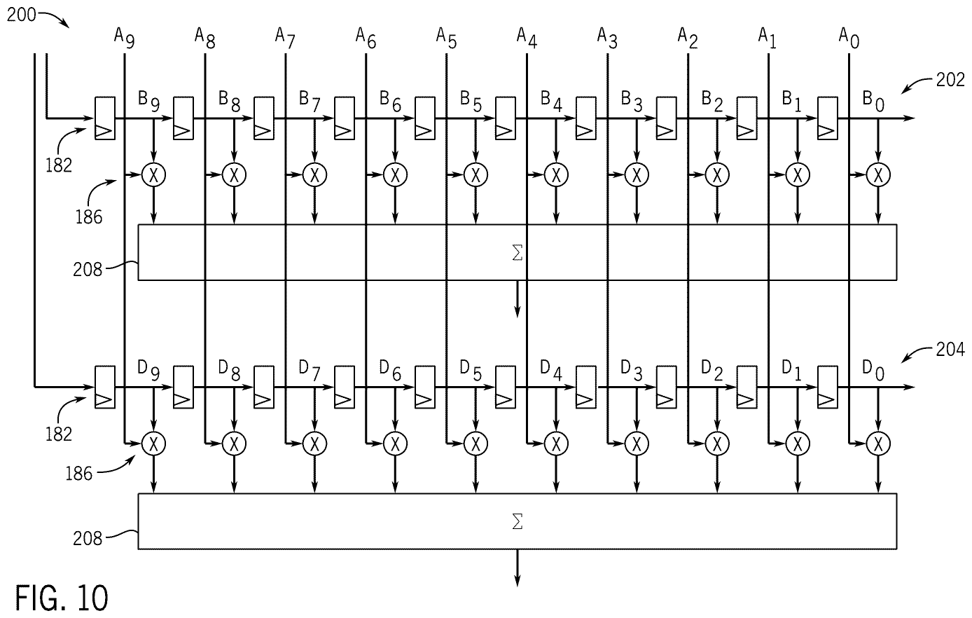

Efficient chains of filters may be formed using other structures that may be present in a DSP block 120. For example, the DSP blocks 120 may include tensor circuitry 200 as shown in FIG. 10. The tensor circuitry 200 may include multiple separate tensor circuits 202, 204. In the example of FIG. 10, the tensor circuitry 200 includes a first tensor circuit 202 and a second tensor circuit 204. Each tensor circuit 202, 204 includes a row of multipliers 186 that multiply a first input vector (e.g., composed of values A0, A1, . . . , A9) with a second input vector (e.g., composed of values B0, B1, . . . , B9 or values D0, D1, . . . , D9). The products of the multipliers 186 may be added together in summation circuitry 208 to produce an overall dot product. Rows of registers 182 may shift in sets or a stream of input data B, D (e.g., vectors, streaming input signal data) to be multiplied by a set of coefficients A (e.g., vectors, weights). Here, there are ten registers 182 in each row, but each row may include any suitable number of registers 182 to correspond with any suitable number of tensor multipliers 186. The result of the summation circuitry 208 may output a value larger than required to represent the size of the tensor, to allow for accumulation in other modes of operation of the DSP Block in tensor mode. For example, an 8×8 multiplier will produce a 16-bit result, and the summation of 10 multipliers will result in a 20-bit result. The summation circuitry 208 may output a sign extended 32-bit result.

It may be seen that the structure of the tensor circuits 202, 204 provide multiplication of inputs and summation of the resulting products, which are operations that also take place in many filters, such as the FIR filter 180 of FIG. 3. Yet the multipliers 186 may have a lower precision than employed in many filters. For example, the multipliers 186 of the tensor circuits 202, 204 may be a row of 6-bit, 7-bit, 8-bit, 9-bit, 10-bit, 11-bit, or 12-bit multipliers. By contrast, many filtering operations may have a precision of 16 bits or higher.

To achieve multiplication with a precision more commonly used in filtering operations, the registers 182 of the tensor circuits 202, 204 can also be repurposed to act as data delay lines and the coefficients input to both tensors 202, 204 instead, creating two FIR filters. The coefficients may be the same for both filters (e.g., values A0, A1, . . . , A9), but this can still be used to create a FIR filter, for example with 16-bit data and 8- bit coefficients (e.g., the tensor multipliers 186 may be INT 8 format). Note that data, coefficients, and the tensor multipliers 186 may be designed to have any suitable format (e.g., INT4, INT6, INT8, INT16, INT18, INT27, and so on).

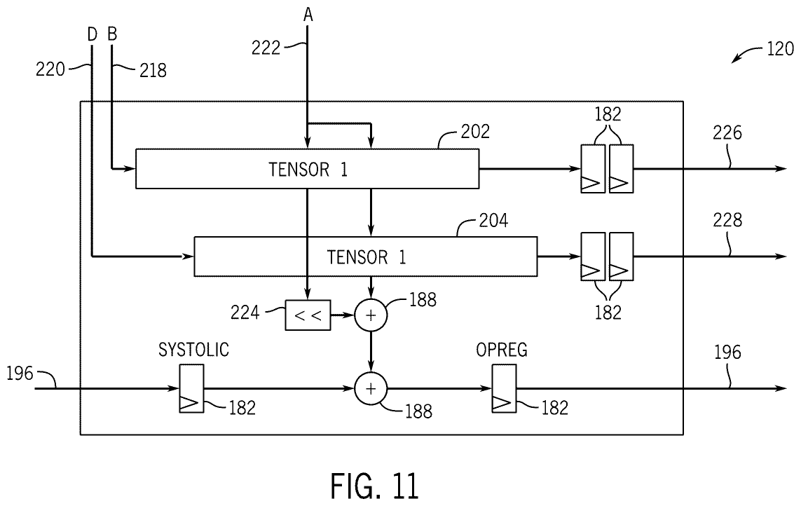

FIG. 11 provides one example of using the tensor circuits 202, 204 of a DSP block 120 to form a multi-tap filter. Inputs 218 and 220 provide input data to the tensor circuits 202 and 204, respectively. By way of example, the input data may be 16-bit data that is split across the two tensor circuits 202, 204 into 8-bit chunks (e.g., bits [8:1] (labeled “B”) into the first tensor circuit 202 via the input 218 and bits [16:9] (labeled “D”) into the second tensor circuit 204 via the input 220). An input 222 may provide the coefficients (e.g., a set of 8-bit coefficients (labeled “A”) corresponding to the number of multipliers of each tensor block 202, 204). Bit shifting circuitry 224 may bit shift the results of the first tensor circuit 202 in relation to the results of the second tensor circuit 204, which may be added together with an adder 188. The amount of shifting performed by the bit-shifting circuitry 224 is based on the size of the data offset due to bitwidth of the input data and coefficients. For example, when the input data (e.g., B, D) are sets of 16-bit data that is split across the two tensor circuits 202, 204 into 8-bit chunks (e.g., bits [8:1] into the first tensor circuit 202 and bits [16:9] into the second tensor circuit 204) and multiplied by a set of 8-bit coefficients, the result of the tensor circuit 202 may be right-shifted by 8 bits to align the significance of its result with that of the tensor circuit 204. Depending on the number of multipliers 186 in the tensor circuits 202, 204, a single DSP block 120 alone may be used to produce a multi-tap filter. For example, if there are 10 multipliers 186 in each tensor circuit 202, 204, one DSP block 120 may be used to produce a 10-tap FIR filter. The results may be added to the results of a previous stage received into a systolic register (“systolic”) register 182 from a direct path 196 from a prior DSP block 120 (not shown), if present, to produce new filter results. The new filter results may enter an output register (“opreg”) register 182 of the present DSP block 120 to be subsequently provided on another direct path 196 to a subsequent DSP block 120 (not shown). The adder 188 may be larger than required to represent the sum of all the tensors in the DSP Block 120, which will allow for the summation of many DSP Blocks 120. The adder 188 may be 64 bits. The direct path 196 and the registers 182 may be 64 bits as well.

Indeed, to create even larger FIR filters using multiple DSP blocks 120, the same cascade and chain delay registers 182 as described above with reference to FIG. 9 may be employed to create a multi-tap systolic FIR filter that spans multiple DSP blocks 120. As shown in FIG. 11, two registers 182 may receive the first part of the data signals (B) output through the first tensor 202 before outputting them on a direct path 226 and two registers 182 may receive the second part of the data signals (D) passing through the second tensor 204 before outputting them on a direct path 228. The direct paths 226 and 228 may form direct connections from one DSP block 120 to another DSP block 120 (e.g., an adjacent DSP block 120 in a column of DSP blocks). This enables data to traverse directly from one DSP block 120 to another DSP block 120 without using additional programmable routing or programmable logic block resources. In effect, the direct path 226 provides input data from the tensor circuit 202 of a first DSP block 120 to the tensor circuit 202 of a second DSP block 120 (not shown). Likewise, the direct path 228 provides input data from the tensor circuit 204 of the first DSP block 120 to the tensor circuit 204 of the second DSP block 120 (not shown).

The two sets of two registers 182 following the tensor circuits 202, 204 add an amount of delay corresponding to the delay due to the output register (“opreg”) register 182 of the present DSP block 120 and to a systolic register (“systolic”) register 182 of a subsequent DSP block 120 (not shown). This allows the formation of filters with a very large number of taps.

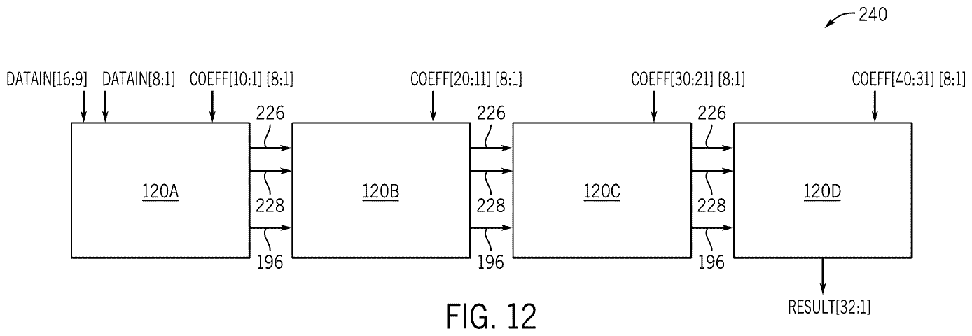

The FIR filter structure of the DSP block 120 of FIG. 11 may be connected to multiple DSP blocks 120 to form a larger FIR filter with even more taps. FIG. 12 illustrates a 40-tap FIR filter 240 formed using multiple connected DSP blocks 120A, 120B, 120C, and 120D based on the arrangement shown in FIG. 11. In FIG. 12, the DSP block 120A receives 16-bit input data broken into two 8-bit chunks shown as datain[8:1] (e.g., bits [8:1] that will feed into the first tensor circuits of the DSP blocks 120A, 120B, 120C, and 120D) and datain [16:9] (e.g., bits [16:9] that will feed into the second tensor circuits of the DSP blocks 120A, 120B, 120C, and 120D). Many coefficients may be applied to the input data as it traverses the DSP blocks 120A, 120B, 120C, and 120D. The first DSP block 120A may receive a first set of ten coefficients (e.g., coefficients [10:1]) of 8 bits [8:1] each, the second DSP block 120B may receive a second set of ten coefficients (e.g., coefficients [20:11]) of 8 bits [8:1] each, the third DSP block 120C may receive a third set of ten coefficients (e.g., coefficients [30:21]) of 8 bits [8:1] each, and the fourth DSP block 120D may receive a fourth set of ten coefficients (e.g., coefficients [40:31]) of 8 bits [8:1] each. For each DSP block 120A, 120B, and 120C, the input data signals may traverse the direct paths 226 and 228 and the results may be provided through direct paths 196 until added to the result from the final DSP block 120D and output by the final DSP block 120D.

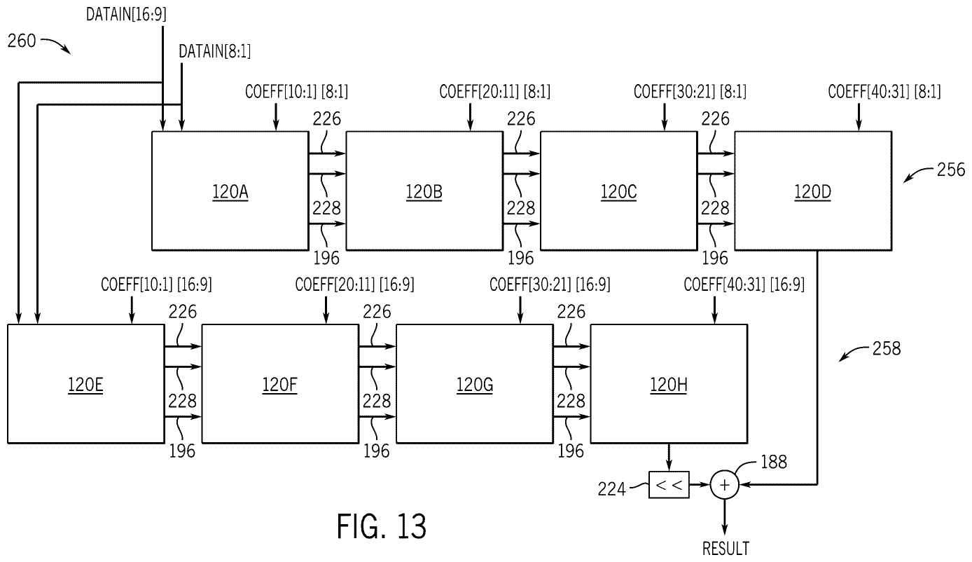

Even larger filters can also be constructed. In FIG. 13, two separate tensor FIRs 256 and 258 of limited data precision can be combined into one tensor FIR 260 with higher data precision, in this case a 16×16 40-tap multiplier. Here, the first tensor FIR 256 is formed in the manner of FIG. 12 using a first set of DSP blocks 120A, 120B, 120C, and 120D. The second tensor FIR 258 is also formed in the manner of FIG. 12 using a second set of DSP blocks 120E, 120F, 120G, and 120H. The DSP block 120A and the DSP block 120E both receive 16-bit input data broken into two 8-bit chunks shown as datain[8:1] (e.g., bits [8:1] that will feed into the first tensor circuits of the DSP blocks 120A, 120B, 120C, and 120D and into the first tensor circuits of the DSP blocks 120E, 120F, 120G, and 120H) and datain [16:9] (e.g., bits [16:9] that will feed into the second tensor circuits of the DSP blocks 120A, 120B, 120C, and 120D and into the second tensor circuits of the DSP blocks 120E, 120F, 120G, and 120H).

The coefficients may be split into two chunks, where the first coefficient chunk is applied to the first tensor FIR filter 256 and the second coefficient chunk is applied to the second tensor FIR filter 258. In the first tensor FIR filter 256, the DSP block 120A may receive the first chunks of a first set of ten coefficients (e.g., coefficients [10:1]) representing the first 8 bits (e.g., [8:1]); the DSP block 120B may receive the first chunks of a second set of ten coefficients (e.g., coefficients [20:11]) representing the first 8 bits (e.g., [8:1]); the DSP block 120C may receive the first chunks of a third set of ten coefficients (e.g., coefficients [30:21]) representing the first 8 bits (e.g., [8:1]); and the DSP block 120D may receive the first chunks of a fourth set of ten coefficients (e.g., coefficients [40:31]) representing the first 8 bits (e.g., [8:1]). Likewise, in the second tensor FIR filter 258, the DSP block 120E may receive the second chunks of the first set of ten coefficients (e.g., coefficients [10:1]) representing the second 8 bits (e.g., [8:1]); the DSP block 120F may receive the second chunks of the second set of ten coefficients (e.g., coefficients [20:11]) representing the second 8 bits (e.g., [8:1]); the DSP block 120G may receive the second chunks of the third set of ten coefficients (e.g., coefficients [30:21]) representing the second 8 bits (e.g., [8:1]); and the DSP block 120H may receive the second chunks of the fourth set of ten coefficients (e.g., coefficients [40:31]) representing the second 8 bits (e.g., [8:1]).

For each DSP block 120A, 120B, and 120C, the input data signals may traverse the direct paths 226 and 228 and the results (here, a 32-bit result due to the use of an 8-bit coefficient and 16-bit data) may be provided through direct paths 196 until added to the result from the final DSP block 120D and output by the final DSP block 120D. Similarly, for each DSP block 120E, 120F, and 120G, the input data signals may traverse the direct paths 226 and 228 and the results (here, a 32-bit result due to the use of an 8-bit coefficient and 16-bit data) may be provided through direct paths 196 until added to the result from the final DSP block 120H and output by the final DSP block 120H.

The result from the second tensor FIR filter 258 may be aligned in significance to the result from the first tensor FIR filter 256 using bit-shifting circuitry 224. The bit-shifting circuitry 224 may left-shift the result from the second tensor FIR filter 258 by any suitable amount (in this example, by 8 bits). This aligns the significance of the result from the second tensor FIR filter 258 with the result from the first tensor FIR filter 256. These values then may be added together in a final adder 188 to produce the final result of the tensor FIR filter 260. Soft logic of the programmable logic circuitry (e.g., LABs 110) may be used to implement the final adder 188.

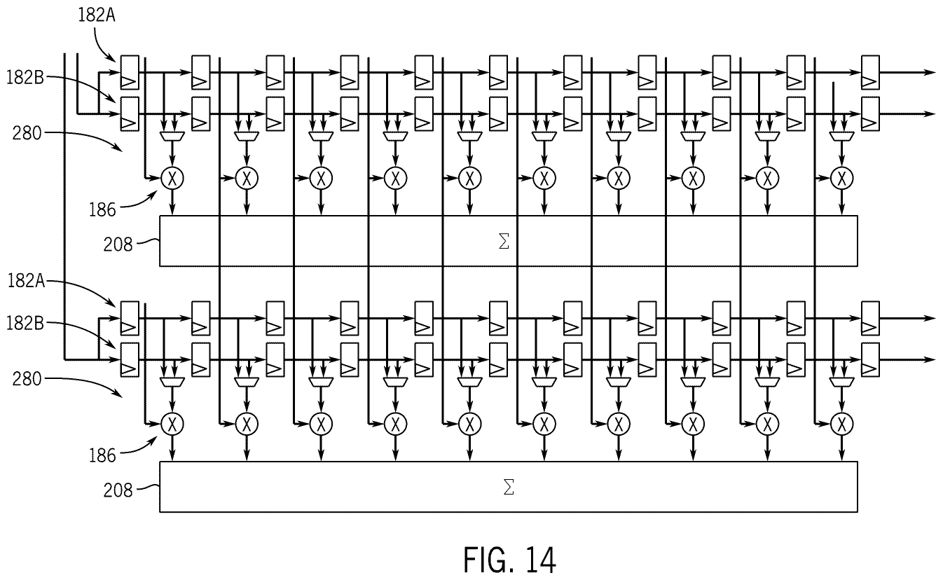

A known structure is to provide banked coefficient registers for the tensor circuits may enable the coefficients to be changed in real time, as shown in FIG. 14. The tensor circuits 202, 204 shown in FIG. 14 include two banks of registers 182A and 182B. The two banks of registers 182A and 182B are provided so that one set of coefficients can be loaded into one bank of registers (e.g., 182A or 182B) while the other bank (e.g., 182B or 182A) is used for processing. A set of multiplexers 280 select the current bank of registers 182A, 182B to use.

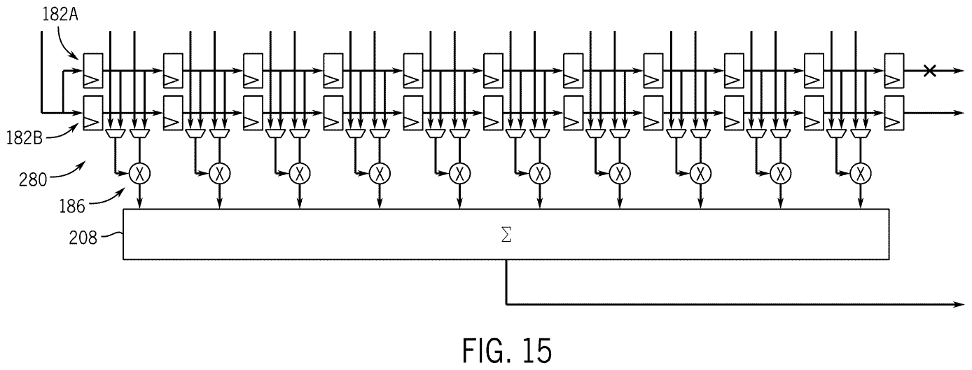

As shown in FIG. 15, an additional set of multiplexers 280 can be provided so that one bank of registers 182 (e.g., can be used for data delay lines while the other is used for weight storage. Although only the first tensor circuit 202 is shown in FIG. 15, the additional set of multiplexers 280 may also be used in the second tensor circuit 204. The coefficients are loaded into one or both of the banks of registers 182A, 182B before the filtering operation is started and the filtering operation may be paused if a new set of coefficients is loaded. The two tensor circuits 202, 204 will then have independent operation of each other. Here, only one of the register banks 182A, 182B may be supported with systolic arrays (whichever one is used for data delay).

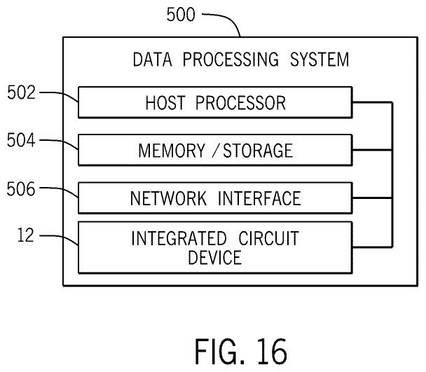

The circuits discussed above may be implemented on the integrated circuit system 12, which may be a component included in a data processing system, such as a data processing system 500, shown in FIG. 16. The data processing system 500 may include the integrated circuit system 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). Moreover, any of the circuit components depicted in FIG. 16 may include the integrated circuit system 12. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit system 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. An integrated circuit device comprising:
a first digital signal processing (DSP) block comprising first hardened arithmetic circuitry and an output register to delay an output of the first DSP block;
a second DSP block comprising second hardened arithmetic circuitry and an input register to receive the output of the first DSP block; and
an input data signal chain of registers comprising:
a first set of registers to provide a respective first set of input data signals to the first DSP block;
a second set of registers to provide a respective second set of the input data signals to the second DSP block; and
a third set of registers connected between the first set of registers and the second set of registers to provide delay equal to that of the output register of the first DSP block and the input register of the second DSP block.

EXAMPLE EMBODIMENT 2. The integrated circuit device of example embodiment 1, wherein the first DSP block, the second DSP block, and the input data signal chain of registers implement a finite impulse response (FIR) filter.

EXAMPLE EMBODIMENT 3. The integrated circuit device of example embodiment 1, wherein the input data signal chain of registers is implemented in programmable logic circuitry of the integrated circuit device.

EXAMPLE EMBODIMENT 4. The integrated circuit device of example embodiment 1, wherein the third set of registers comprises registers having delay equal to that of the output register of the first DSP block and the input register of the second DSP block.

EXAMPLE EMBODIMENT 5. The integrated circuit device of example embodiment 1, wherein the output register of the first DSP block is connected directly to the input register of the second DSP block without intervening programmable logic circuitry.

EXAMPLE EMBODIMENT 6. The integrated circuit device of example embodiment 1, wherein:
the hardened arithmetic circuitry of the first DSP block comprises:

first hardened multiplication circuitry to multiply the first set of the input data signals with a first set of coefficients to produce a first set of filter products; and
first addition circuitry to sum the first set of filter products to obtain a first sum;
wherein the output register of the first DSP block is configurable to receive and delay the first sum as the output of the first DSP block; and
the hardened arithmetic circuitry of the second DSP block comprises:
second hardened multiplication circuitry to multiply the second set of the input data signals with a second set of coefficients to produce a second set of filter products; and
second addition circuitry to receive the first sum from the input register and sum the first sum and the second set of filter products to obtain a second sum as an output of the second DSP block.

EXAMPLE EMBODIMENT 7. The integrated circuit device of example embodiment 6, wherein the first multiplication circuitry and the second multiplication circuitry respectively comprise at least four separate multipliers.

EXAMPLE EMBODIMENT 8. The integrated circuit device of example embodiment 1, wherein:
the second DSP block comprises a second output register to delay an output of the second DSP block;
the integrated circuit device comprises a third DSP block comprising third hardened arithmetic circuitry and a second input register configurable to receive the output of the second DSP block; and
the input data signal chain of registers comprises:
a fourth set of registers to provide a respective third set of input data signals to the third DSP block; and
a fifth set of registers connected between the second set of registers and the fourth set of registers to provide delay equal to that of the second output register of the second DSP block and the second input register of the third DSP block.

EXAMPLE EMBODIMENT 9. Filter circuitry comprising:
a first tensor circuit to multiply first components of a set of input data signals with first components of a set of coefficients;
a second tensor circuit to multiply second components of the set of input data signals with the first components of the set of coefficients;
bit-shifting circuitry to shift results output by the first tensor circuit in relation to results output by the second tensor circuit to produce shifted first tensor results; and
addition circuitry to sum the shifted first tensor results with the results output by the second tensor circuit to produce a first output signal.

EXAMPLE EMBODIMENT 10. The filter circuitry of example embodiment 9, comprising:
an output register to delay the first output signal;
an input register to receive the first output signal from the output register;
a first set of delay registers to provide delay equal to that of the output register and the input register, wherein the first set of delay registers sequentially holds the first components of the set of input data signals from the first tensor circuit;
a second set of delay registers to provide delay equal to that of the output register and the input register, wherein the second set of delay registers sequentially holds the second components of the set of input data signals from the second tensor circuit;
a third tensor circuit to receive the first components of the set of input data signals from the first set of delay registers and multiply the first components of the set of input data signals with second components of a set of coefficients;
a fourth tensor circuit to receive the second components of the set of input data signals from the second set of delay registers and multiply the second components of the set of input data signals with the second components of the set of coefficients;
second bit-shifting circuitry to shift results output by the third tensor circuit in relation to results output by the fourth tensor circuit to produce shifted third tensor results; and
second addition circuitry to receive the first output signal from the input register and sum the shifted third tensor results, the results output by the fourth tensor circuit, and the first output signal to produce a second output signal.

EXAMPLE EMBODIMENT 11. The filter circuitry of example embodiment 10, wherein:
the first tensor circuit, the second tensor circuit, the bit-shifting circuitry, the addition circuitry, the output register, the first set of delay registers, and the second set of delay registers are part of a first digital signal processing (DSP) block of a programmable logic device; and
the third tensor circuit, the fourth tensor circuit, the second bit-shifting circuitry, the second addition circuitry, and the input register are part of a second DSP block of the programmable logic device.

EXAMPLE EMBODIMENT 12. The filter circuitry of example embodiment 11, comprising a direct path between the output register of the first DSP block and the input register of the second DSP block.

EXAMPLE EMBODIMENT 13. The filter circuitry of example embodiment 11, comprising:
a first direct path between a last of the first set of delay registers and the third tensor circuit; and
a second direct path between a last of the second set of delay registers and the fourth tensor circuit.

EXAMPLE EMBODIMENT 14. The filter circuitry of example embodiment 9, wherein the filter circuitry forms a component of a multi-tap finite impulse response (FIR) filter with 10 or more taps. EXAMPLE EMBODIMENT 15. The filter circuitry of example embodiment 9, wherein the filter circuitry forms a component of a multi-tap finite impulse response (FIR) filter with 40 or more taps.

EXAMPLE EMBODIMENT 16. The filter circuitry of example embodiment 9,wherein the filter circuitry comprises a pipeline of digital signal processing (DSP) blocks, wherein:
a first DSP block of the pipeline of DSP blocks receives, from outside the pipeline of DSP blocks, the first components of the set of input data signals, the second components of the set of input data signals, and the first components of the set of coefficients; and
subsequent DSP blocks of the pipeline of DSP blocks receive:
from outside the pipeline of DSP blocks, additional components of the set of coefficients; and
from a previous DSP block of the pipeline of DSP blocks, the first components of the set of input data signals and the second components of the set of input data signals.

EXAMPLE EMBODIMENT 17. The filter circuitry of example embodiment 16, wherein the filter circuitry comprises parallel pipelines of digital signal processing (DSP) blocks, wherein:
in a first pipeline of the parallel pipelines:
a first DSP block of the first pipeline receives, from outside the first pipeline, the first components of the set of input data signals, the second components of the set of input data signals, and the first components of the set of coefficients, wherein the first components of the set of coefficients comprise bits of a first significance; and
subsequent DSP blocks of the first pipeline receive:
from outside the first pipeline, additional components of the set of coefficients, wherein the additional components of the set of coefficients comprise bits of the first significance; and
from a previous DSP block of the first pipeline, the first components of the set of input data signals and the second components of the set of input data signals; and
in a second pipeline of the parallel pipelines:
a first DSP block of the second pipeline receives, from outside the second pipeline, the first components of the set of input data signals, the second components of the set of input data signals, and second components of the set of coefficients, wherein the second components of the set of coefficients comprise bits of a second significance greater than the first significance; and
subsequent DSP blocks of the second pipeline receive:
from outside the second pipeline, second additional components of the set of coefficients, wherein the second additional components of the set of coefficients comprise bits of the second significance; and
from a previous DSP block of the second pipeline, the first components of the set of input data signals and the second components of the set of input data signals.

EXAMPLE EMBODIMENT 18. Digital signal processing circuitry comprising:
a first set of pipelined registers;
a second set of pipelined registers in parallel to the first set of pipelined registers;
a set of multiplexers respectively configurable to select from between an output of a respective register from the first set of pipelined registers and an output of a respective register from the second set of pipelined registers;
a set of multipliers configurable to multiply an output of a respective multiplexer of the set of multiplexers with a respective multiplicand; and
addition circuitry configurable to sum a set of products from the set of multipliers.

EXAMPLE EMBODIMENT 19. The digital signal processing circuitry of example embodiment 18, comprising:
a third set of pipelined registers;
   a fourth set of pipelined registers in parallel to the third set of pipelined registers;
   a second set of multiplexers respectively configurable to select from between an output of a respective register from the third set of pipelined registers and an output of a respective register from the fourth set of pipelined registers;
   a second set of multipliers configurable to multiply an output of a respective multiplexer of the second set of multiplexers with a respective multiplicand; and
   second addition circuitry configurable to sum a second set of products from the second set of multipliers.

EXAMPLE EMBODIMENT 20. The digital signal processing circuitry of example embodiment 18, comprising:
a second set of multiplexers respectively configurable to select from between the output of a respective register from the first set of pipelined registers and a respective input value of the second set of multiplexers;
wherein the set of multipliers is configurable to multiply the output of a respective multiplexer of the set of multiplexers with the respective multiplicand, wherein the respective multiplicand comprises a respective output of the second set of multiplexers.

What is claimed is:

1. An integrated circuit device comprising:
a first digital signal processing (DSP) block comprising first hardened arithmetic circuitry and an output register to delay an output of the first DSP block;
a second DSP block comprising second hardened arithmetic circuitry and an input register to receive the output of the first DSP block; and
an input data signal chain of registers comprising:
a first set of registers to provide a respective first set of input data signals to the first DSP block;
a second set of registers to provide a respective second set of the input data signals to the second DSP block; and
a third set of registers connected between the first set of registers and the second set of registers to provide delay equal to that of the output register of the first DSP block and the input register of the second DSP block.

2. The integrated circuit device of claim 1, wherein the first DSP block, the second DSP block, and the input data signal chain of registers implement a finite impulse response (FIR) filter.

3. The integrated circuit device of claim 1, wherein the input data signal chain of registers is implemented in programmable logic circuitry of the integrated circuit device.

4. The integrated circuit device of claim 1, wherein the third set of registers comprises registers having delay equal to that of the output register of the first DSP block and the input register of the second DSP block.

5. The integrated circuit device of claim 1, wherein the output register of the first DSP block is connected directly to the input register of the second DSP block without intervening programmable logic circuitry.

6. The integrated circuit device of claim 1, wherein:
the hardened arithmetic circuitry of the first DSP block comprises:
first hardened multiplication circuitry to multiply the first set of the input data signals with a first set of coefficients to produce a first set of filter products; and
first addition circuitry to sum the first set of filter products to obtain a first sum;
wherein the output register of the first DSP block is configurable to receive and delay the first sum as the output of the first DSP block; and
the hardened arithmetic circuitry of the second DSP block comprises:
second hardened multiplication circuitry to multiply the second set of the input data signals with a second set of coefficients to produce a second set of filter products; and
second addition circuitry to receive the first sum from the input register and sum the first sum and the second set of filter products to obtain a second sum as an output of the second DSP block.

7. The integrated circuit device of claim 6, wherein the first multiplication circuitry and the second multiplication circuitry respectively comprise at least four separate multipliers.

8. The integrated circuit device of claim 1, wherein:
the second DSP block comprises a second output register to delay an output of the second DSP block;
the integrated circuit device comprises a third DSP block comprising third hardened arithmetic circuitry and a second input register configurable to receive the output of the second DSP block; and
the input data signal chain of registers comprises:
a fourth set of registers to provide a respective third set of input data signals to the third DSP block; and
a fifth set of registers connected between the second set of registers and the fourth set of registers to provide delay equal to that of the second output register of the second DSP block and the second input register of the third DSP block.

9. Filter circuitry comprising:
a first tensor circuit to multiply first components of a set of input data signals with first components of a set of coefficients;
a second tensor circuit to multiply second components of the set of input data signals with the first components of the set of coefficients;
bit-shifting circuitry to shift results output by the first tensor circuit in relation to results output by the second tensor circuit to produce shifted first tensor results; and
addition circuitry to sum the shifted first tensor results with the results output by the second tensor circuit to produce a first output signal.

10. The filter circuitry of claim 9, comprising:
an output register to delay the first output signal;
an input register to receive the first output signal from the output register;
a first set of delay registers to provide delay equal to that of the output register and the input register, wherein the first set of delay registers sequentially holds the first components of the set of input data signals from the first tensor circuit;
a second set of delay registers to provide delay equal to that of the output register and the input register, wherein the second set of delay registers sequentially holds the second components of the set of input data signals from the second tensor circuit;
a third tensor circuit to receive the first components of the set of input data signals from the first set of delay registers and multiply the first components of the set of input data signals with second components of a set of coefficients;
a fourth tensor circuit to receive the second components of the set of input data signals from the second set of delay registers and multiply the second components of the set of input data signals with the second components of the set of coefficients;
second bit-shifting circuitry to shift results output by the third tensor circuit in relation to results output by the fourth tensor circuit to produce shifted third tensor results; and
second addition circuitry to receive the first output signal from the input register and sum the shifted third tensor results, the results output by the fourth tensor circuit, and the first output signal to produce a second output signal.

11. The filter circuitry of claim 10, wherein:
the first tensor circuit, the second tensor circuit, the bit-shifting circuitry, the addition circuitry, the output register, the first set of delay registers, and the second set of delay registers are part of a first digital signal processing (DSP) block of a programmable logic device; and
the third tensor circuit, the fourth tensor circuit, the second bit-shifting circuitry, the second addition circuitry, and the input register are part of a second DSP block of the programmable logic device.

12. The filter circuitry of claim 11, comprising a direct path between the output register of the first DSP block and the input register of the second DSP block.

13. The filter circuitry of claim 11, comprising:
a first direct path between a last of the first set of delay registers and the third tensor circuit; and
a second direct path between a last of the second set of delay registers and the fourth tensor circuit.

14. The filter circuitry of claim 9, wherein the filter circuitry forms a component of a multi-tap finite impulse response (FIR) filter with 10 or more taps.

15. The filter circuitry of claim 9, wherein the filter circuitry forms a component of a multi-tap finite impulse response (FIR) filter with 40 or more taps.

16. The filter circuitry of claim 9, wherein the filter circuitry comprises a pipeline of digital signal processing (DSP) blocks, wherein:
a first DSP block of the pipeline of DSP blocks receives, from outside the pipeline of DSP blocks, the first components of the set of input data signals, the second components of the set of input data signals, and the first components of the set of coefficients; and
subsequent DSP blocks of the pipeline of DSP blocks receive:
from outside the pipeline of DSP blocks, additional components of the set of coefficients; and
from a previous DSP block of the pipeline of DSP blocks, the first components of the set of input data signals and the second components of the set of input data signals.

17. The filter circuitry of claim 16, wherein the filter circuitry comprises parallel pipelines of digital signal processing (DSP) blocks, wherein:
in a first pipeline of the parallel pipelines:
a first DSP block of the first pipeline receives, from outside the first pipeline, the first components of the set of input data signals, the second components of the set of input data signals, and the first components of the set of coefficients, wherein the first components of the set of coefficients comprise bits of a first significance; and
subsequent DSP blocks of the first pipeline receive:
from outside the first pipeline, additional components of the set of coefficients, wherein the additional components of the set of coefficients comprise bits of the first significance; and
from a previous DSP block of the first pipeline, the first components of the set of input data signals and the second components of the set of input data signals; and
in a second pipeline of the parallel pipelines:
a first DSP block of the second pipeline receives, from outside the second pipeline, the first components of the set of input data signals, the second components of the set of input data signals, and second components of the set of coefficients, wherein the second components of the set of coefficients comprise bits of a second significance greater than the first significance; and
subsequent DSP blocks of the second pipeline receive:
from outside the second pipeline, second additional components of the set of coefficients, wherein the second additional components of the set of coefficients comprise bits of the second significance; and
from a previous DSP block of the second pipeline, the first components of the set of input data signals and the second components of the set of input data signals.

18. Digital signal processing circuitry comprising:
a first set of pipelined registers;
a second set of pipelined registers in parallel to the first set of pipelined registers;
a set of multiplexers respectively configurable to select from between an output of a respective register from the first set of pipelined registers and an output of a respective register from the second set of pipelined registers;
a set of multipliers configurable to multiply an output of a respective multiplexer of the set of multiplexers with a respective multiplicand; and
addition circuitry configurable to sum a set of products from the set of multipliers.

19. The digital signal processing circuitry of claim 18, comprising:
a third set of pipelined registers;
a fourth set of pipelined registers in parallel to the third set of pipelined registers;
a second set of multiplexers respectively configurable to select from between an output of a respective register from the third set of pipelined registers and an output of a respective register from the fourth set of pipelined registers;
a second set of multipliers configurable to multiply an output of a respective multiplexer of the second set of multiplexers with a respective multiplicand; and
second addition circuitry configurable to sum a second set of products from the second set of multipliers.

20. The digital signal processing circuitry of claim 18, comprising:
a second set of multiplexers respectively configurable to select from between the output of a respective register from the first set of pipelined registers and a respective input value of the second set of multiplexers;
wherein the set of multipliers is configurable to multiply the output of a respective multiplexer of the set of multiplexers with the respective multiplicand, wherein the respective multiplicand comprises a respective output of the second set of multiplexers.
